(19) United States
(12) Patent Application Publication
(10) Pub. No.: US 2007/0090536 A1
(43) Pub. Date: Apr. 26, 2007

(54) Sensor having semiconductor chip and circuit chip

(75) Inventors: Minekazu Sakai, Kariya-city (JP); Ryuichiro Abe, Ichinomiya-city (JP); Yasunori Ninomiya, Kariya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/522,916

(22) Filed: Sep. 19, 2006

(30) Foreign Application Priority Data
Oct. 21, 2005 (JP) 2005-307031

(51) Int. Cl. H01L 23/48

(52) U.S. Cl. 257/778

(57) ABSTRACT

A sensor includes: a semiconductor chip having a sensing portion; a circuit chip; and first and second films. The sensing portion is disposed on a first side of the semiconductor chip. The first side of the semiconductor chip is electrically connected to the circuit chip through a bump. The first side of the semiconductor chip faces the circuit chip. The first film is disposed on the first side of the semiconductor chip. The first film covers the sensing portion, and is made of resin, and the second film is made of resin, and disposed on a second side of the semiconductor chip.

### CROSS REFERENCE TO RELATED APPLICATION

This application is based on Japanese Patent Application No. 2005-307031 filed on Oct. 21, 2005, the disclosure of which is incorporated herein by reference.

### FIELD OF THE INVENTION

The present invention relates to a sensor having a semiconductor chip and a circuit chip.

### BACKGROUND OF THE INVENTION

Conventionally, various sensor apparatus have been proposed (refer to, for example, JP-A-2001-217280). That is, in a conventional sensor apparatus, when a semiconductor chip having a sensing portion on one plane of this semiconductor chip is electrically connected to a circuit chip, the semiconductor chip and the circuit chip are stacked on each other, and then, a bump is interposed between these semiconductor chip and circuit chip so as to electrically connect these chips with each other. The sensing portion of the semiconductor chip senses physical quantity such as angular velocities, acceleration, and pressure.

While the inventors of the present invention decided to employ such a structure that a semiconductor chip and a circuit chip are stacked via a bump on each other under the condition that one plane of the semiconductor chip, namely one plane thereof having a sensing portion is located opposite to one plane of the circuit chip, the inventors investigate this structure.

As to sensing portions for sensing mechanical amounts, there are many sensing portions having movable portions. If foreign substances are adhered with respect to these sensing portions when bump connections are performed, there is such a risk that sensing characteristics of these sensing portions are largely varied. To this end, the inventors considered such a technical idea that resin films capable of covering the sensing portions are joined to one planes of semiconductor chips in order to protect these sensing portions.

However, there is a large difference between linear expansion coefficients as to a semiconductor chip, which is made of a semiconductor such as silicon, and a film, which is made of a resin. As a result, the inventors recognize that since stresses (distortions) are produced due to this large difference between the linear expansion coefficients by temperature cycles and the like, the semiconductor chip is curved.

In the case that such a curve of the semiconductor chip occurs, a sensing portion in this curved semiconductor chip is deformed. As previously explained, as to the sensing portions for detecting the mechanical amounts, there are many sensing portions having the movable portions, so that deformations of these sensing portions may conduct variations of sensor characteristics. In other words, the temperature characteristics of the sensors may be deteriorated due to the temperature cycle.

### SUMMARY OF THE INVENTION

In view of the above-described problem, it is an object of the present disclosure to provide a sensor having a semiconductor chip and a circuit chip.

According to a first aspect of the present disclosure, a sensor includes: a semiconductor chip having a sensing portion for detecting a physical quantity; a circuit chip; and first and second films. The sensing portion is disposed on a first side of the semiconductor chip. The first side of the semiconductor chip is electrically connected to the circuit chip through a bump. The first side of the semiconductor chip faces the circuit chip so that the sensing portion also faces the circuit chip. The first film is disposed on the first side of the semiconductor chip. The first film covers the sensing portion, and is made of resin, and the second film is made of resin, and disposed on a second side of the semiconductor chip.

In the above device, the semiconductor chip is sandwiched between the first and second films. Therefore, both interfaces between the semiconductor chip and the first and second films have stress. The stress is caused by a difference of linear coefficient of expansion between the semiconductor chip and the first or second film. Accordingly, deformation of the semiconductor chip caused by the difference of linear coefficient of expansion is reduced.

According to a second aspect of the present disclosure, a sensor includes: a semiconductor chip having a sensing portion for detecting a physical quantity; a circuit chip; first and second films; and a solder bump for electrically connecting between the semiconductor chip and the circuit chip. The second film, the semiconductor chip, the first film, and the circuit chip are stacked in a stacking direction in this order. The semiconductor chip includes first and second sides. The circuit chip includes first and second sides. The first side of the semiconductor chip is electrically connected to the first side of the circuit chip through the bump so that the bump is embedded in the first film. The sensing portion is disposed on the first side of the semiconductor chip. The sensing portion separates from the first film so that a space is provided between the sensing portion and the first film. The first film is made of resin, and the second film is made of resin.

In the above device, the semiconductor chip is sandwiched between the first and second films. Therefore, both interfaces between the semiconductor chip and the first and second films have stress. The stress is caused by a difference of linear coefficient of expansion between the semiconductor chip and the first or second film. Accordingly, deformation of the semiconductor chip caused by the difference of linear coefficient of expansion is reduced.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing an angular velocity sensor apparatus;

FIG. 2 is a plan view showing a circuit chip in the device shown in FIG. 1;

FIGS. 3A and 3B are cross sectional views explaining a method for manufacturing the device in FIG. 1;

FIG. 4 is a cross sectional view showing another angular velocity sensor apparatus;

FIG. 5 is a cross sectional view showing further another angular velocity sensor apparatus;

FIG. 6 is a cross sectional view showing another angular velocity sensor apparatus; and

FIG. 7 is a cross sectional view showing another angular velocity sensor apparatus.

### DETAILED DESCRIPTION OF THE PREFERRED EMBODIMENTS

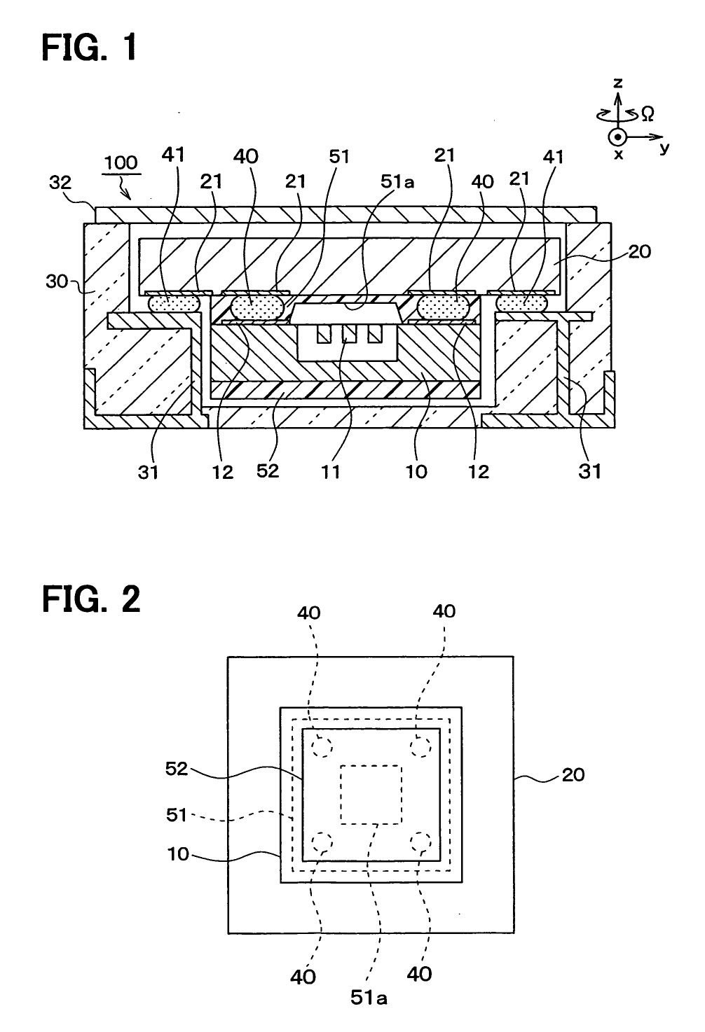

FIG. 1 is a sectional view for schematically showing an entire structure of an angular velocity sensor apparatus 100 functioning as a sensor apparatus according to a first example embodiment. FIG. 2 is a plan view for schematically indicating one plane of a circuit chip 20 of the angular velocity sensor apparatus 100 indicated in FIG. 1, namely, a plane structure of the circuit chip 20 on the side of a mounting plane thereof for a semiconductor chip 10.

As indicated in FIG. 1, the angular velocity sensor apparatus 100 of this first embodiment has been mainly constituted by employing a sensor chip 10 as a semiconductor chip, a circuit chip 20, and a package 30 for storing the sensor chip 10 and the circuit chip 20 thereinto.

In this first embodiment, the sensor chip 10 has been constructed as the semiconductor chip for sensing angular velocities as physical quantity. A vibrator member 11 has been provided on the side of one plane of this sensor chip 10, while the vibrator member 11 corresponds to a sensing portion as well as a movable portion.

Such a sensor chip 10 is formed in such a manner that, for example, the micromachine processing operation which is well known in the technical field is carried out with respect to a semiconductor substrate, for instance, an SOI (silicon-on-insulator) substrate. In this first embodiment, the sensor chip 10 is made in a rectangular plate shape as shown in FIG. 2.

Concretely speaking, the vibrator 11 in the sensor chip 10 may be constructed as a beam structural body having a comb structure, which is generally known. The vibrator 11 is supported by a beam having an elastic characteristic, and is movable in response to an application of an angular velocity.

Then, in FIG. 1, when the vibrator 11 is driven to be vibrated along an “x” axis direction, if an angular velocity “Ω” around a “z” axis is applied to this vibrator 11, then the vibrator 11 is driven to be vibrated by receiving Coriolis force along a “y” axis direction perpendicular to the above-explained x axis.

Then, while a detecting-purpose electrode (not shown) is provided on the sensor chip 10, the sensor chip 10 is capable of detecting the angular velocity “Ω” by detecting a change in electrostatic capacities between the own detecting-purpose electrode and the vibrator 11 due to detecting vibrations of the vibrator 11. As previously explained, the sensor chip 10 detects the angular velocity “Ω” based upon the vibrations of the vibrator 11.

A pad 12 has been provided on a proper position of one plane of this sensor chip 10. This pad 12 is employed so as to apply a voltage to the vibrator 11, and also to derive signals from the vibrator 11.

Then, a bump 40 has been connected to this pad 12, while the bump 40 is made of a gold bump, a solder bump, and the like. Concretely speaking, as indicated in FIG. 1, this bump 12 has been provided on a peripheral portion of the sensor chip 10. Such a pad 12 is made of, for example, aluminum.

This bump 40 may be manufactured by employing various sorts of bump forming methods such as a general method for forming a stud bump, a method of forming a solder bump, or a screen printing method using conductive paste such as gold, or a printing method by an ink jetting method which uses paste of gold.

Then, one plane of the sensor chip 10 and one plane of the circuit chip 20 have been stacked on each other via the bump 40 in such a manner that these planes of the sensor chip 10 and of the circuit chip 20 are located opposite to each other. That is to say, the sensor chip 10 has been stacked on the circuit chip 20 under such a condition that the vibrator 11 is located opposite to one plane of the circuit chip 20, while both these chips 10 and 20 have been electrically connected to each other via the bump 40.

Also, the circuit chip 20 has been constructed as a signal processing chip having various functions, for instance, this signal processing chip transfers a driving signal and a detecting signal to the sensor chip 10, processes an electric signal from the sensor chip 10, and outputs the processed signal to an external circuit (not shown).

In this example, as indicated in FIG. 1, a pad 12 of the sensor chip 10 has been connected via the bump 40 to a pad 21 of the circuit chip 20. Also, in the angular velocity sensor apparatus 100, an interval between both the sensor chip 10 and the circuit chip 20 is secured by the bump 40, and the vibrator 11 is separated from the circuit chip 20.

The above-explained circuit chip 20 includes an IC chip, or the like. For example, in this IC chip, MOS transistors and bipolar transistors have been manufactured with respect to a silicon substrate, and the like, by employing a semiconductor process which is well known in this technical field. In this example, the circuit chip 20 is made in a rectangular shaped chip (refer to FIG. 2).

As explained above, an electric signal derived from the sensor chip 10 is supplied via the bump 40 to the circuit chip 20. Then, for example, this supplied electric signal is converted into a voltage signal by way of a C/V converting circuit, or the like, provided in the circuit chip 20, and then, the converted voltage signal is outputted as an angular velocity signal.

In this first embodiment, a first film 51 has been joined to one plane of the sensor chip 10 opposite to the circuit chip 20, while the first film 51 is made of a resin and covers the vibrator 11 functioning as the sensing portion. Also, a second film 52 has been joined to the other plane of the sensor chip 10, which is located opposite to one plane of this sensor chip 10. The second film 52 is made of a resin.

The first film 51, the second film 52, and the angular velocity detecting element 10 constitute rectangular-shaped sheet form. As represented in FIG. 1, outer edge portions of these three members 10, 51, and 52 are made substantially coincident with each other along the stacked layer direction of both the chips 10 and 20.

In other words, outer peripheral shapes of the first film 51 and the second film 52 own essentially same shape as the outer peripheral shape of the sensor chip 10, and further, are rectangular shapes having the same dimensions. However, in FIG. 2, for the sake of convenience, these three members 10, 51, and 52 are discriminatable from each other by intentionally shifting outer edge portions of these three members 10, 51, and 52.

The first film 51 and the second film 52 are made of resin films having non-conductive characteristics, and generally speaking, have employed so-called “NCF (Non Conductive Film).”

As such films 51 and 52, film materials may be employed which are joined to each other by a crimping method, a thermal crimping method, or an adhering method. Otherwise, films formed by printing methods such as screen printing method and an ink jetting method may be employed.

Concretely speaking, as to these films 51 and 52, such a film made of a resin having an electric insulating characteristic is employed, for instance, a film made of an epoxy series resin, a polyimide series resin, and the like is employed. The films 51 and 52 made of such resins are softened by applying heat thereto, and are hardened by continuously applying heat thereto under such a condition that these films 51 and 52 have been softened.

In this case, the resins which constitute the first film 51 and the second film 52 may be different from each other in such a way that the first film 51 is made of a polyimide series resin film, and the second film 52 is made of an epoxy series resin. However, in this example, it is so assumed that resins which constitute both the first film 51 and the second film 52 are made of the same material.

Such a fact that resins which constitute both the first film 51 and the second film 52 are made of the same material implies that both the first and second films 51 and 52 are made of epoxy series resins, and chemical structural formula and chemical composition of this epoxy series resin are identical to each other.

Then, in this example, as shown in FIG. 1, the first film 51 has been arranged in such a manner that this first film 51 embeds a space between one plane of the sensor chip 10 and one plane of the circuit chip 20, which are located opposite to each other, and also, has been joined to one plane of the circuit chip 20.

In this example, as indicated in FIG. 1 and FIG. 2, the first film 51 is also provided around the bump 40 between the sensor chip 10 and the circuit chip 20, so that the bump 40 is sealed by this first film 51.

The first film 51 is filled between the sensor chip 10 and the circuit chip 20 around the bump 40, and is joined to both these chips 10 and 20 in the above-explained manner. As a result, under the above-described condition, the mechanical connection and the supporting effect between these chips 10 and 20 may be achieved not only by the bump 40, but also by the first film 51.

Also, the first film 51 has been joined to one plane of the sensor chip 10 under such a condition that the first film 51 is separated from the vibrator 11. In this case, as shown in FIG. 1 and FIG. 2, a concave 51a has been formed in a portion of the first film 51, which corresponds to the vibrator 11.

In the first film 51, the portion of this concave 51a is made thinner than that of a peripheral portion of this concave 51a. The first film 51 is separated from the vibrator 11 by this concave 51a, so that the vibrator 11 and the first film 51 are under non-contact condition.

Then, the first film 51 has been joined with respect to the sensor chip 10 at portions other than the concave 51a, namely at a peripheral portion of the concave 51a. As a result, the vibrator 11 is covered by the first film 51, so that it is possible to avoid a penetration of alien substance.

Also, as represented in FIG. 1, the circuit chip 20 has been electrically and mechanically connected via the bump 41 with respect to the package 30. This bump 41 is similar to the bump 40 which connects the sensor chip 10 to the circuit chip 20.

The package 30 of the first embodiment has a wiring line 31 which is made of a conductive material on an inner portion, or a surface. Although not specifically limited, this package 30 may be made of ceramics, a resin, and the like. This package 30 may be constituted as a ceramic stacked layer wiring board in which, for example, a plurality of ceramics layers such as alumina have been stacked on each other.

In such a stacked layer wiring board, the above-explained wiring lines 31 have been formed among the respective layers, and these wiring lines 31 have been conducted to each other by way of through holes. Then, as represented in FIG. 1, the pad 21 of the circuit board 20 has been electrically and mechanically connected to the above-explained wiring line 31 located on the surface of the package 30 by the bump 41.

In the example shown in FIG. 1, the wiring line 31 is exposed to a stepped portion internally provided in the package 30, while the peripheral portion of one plane of the circuit chip 20 is supported by this stepped portion. Then, the pad 21 of the circuit chip 20 has been connected via the bump 41 to the wiring line 31 of the package 30 via the bump 41.

In this first embodiment, a plane size of the sensor chip 10 is smaller than a plane size of the circuit chip 20, whereas the circuit chip 20 is one size larger than the sensor chip 10. Since the outer peripheral edge portion of the sensor chip 10 is positioned inside of the outer peripheral edge portion of the circuit chip 20, the circuit chip 20 is connectable to the package 30 at the peripheral portion of one plane of this circuit chip 20.

As previously explained, the sensor chip 10 and the circuit chip 20 have been electrically connected via the above-explained bump 41 and the wiring line 31 of the package 30 to the external unit. For example, an output signal from the circuit chip 20 is fed via the bump 41 from the wiring line 31 of the package 30 to the external unit.

Also, as indicated in FIG. 1, a lid 32 has been mounted and fixed on an opening portion of the package 30, and thus, the internal portion of the package 30 has been sealed by this lid portion 32. This lid portion 32 is made of ceramics, a resin, a metal, or the like. The lid portion 32 has been joined to the package 30 by way of an adhering method, a welding method, a soldering method, or the like.

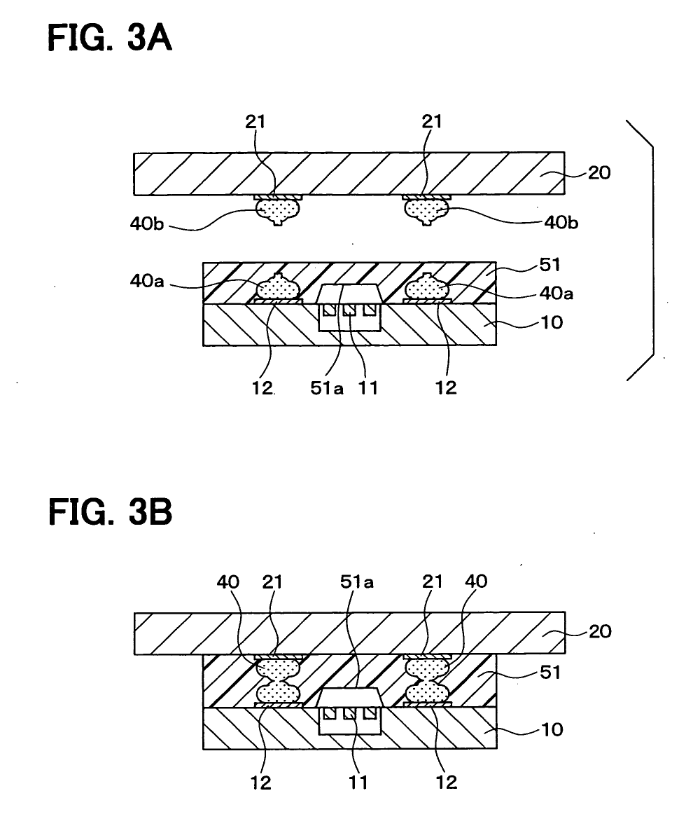

Next, a description is made of a method for manufacturing the angular velocity sensor apparatus 100 according to this first embodiment. FIG. 3A and FIG. 3B are step diagrams for showing a method of connecting the sensor chip 10 to the circuit chip 20 via the bump 40 in this manufacturing method.

As indicated in FIG. 3A, the sensor chip 10 where a bump 40a has been formed on one plane thereof, and the circuit chip 20 where another bump 40b has been formed on one plane thereof are prepared.

In this case, while the bumps 40a and 40b have been formed on both the sensor and circuit chips 10 and 20, the bump 40a formed on the sensor chip 10 is joined to the bump 40b formed on the circuit chip 20, so that these bumps 40a and 40b constitute the above-explained bump 40 for joining these chips 10 and 20.

In this example, the bumps 40a and 40b formed on the side of both the sensor and circuit chips 10 and 20 are gold bumps which have been formed by employing a wire bonding apparatus, or the like. Then, in this example, as indicated in FIG. 3A, the first film 51 is adhered to one plane of the sensor chip 10.

In this connecting method, while the above-explained concave 51a has been previously formed in the first film 51 by performing a press process, a stamp process, or the like, the adhering operation of the first film 51 is carried out under such a positioning condition that this concave 51a is made coincident with the vibrator 11 on one plane of the sensor chip 10.

The adhering operation of the first film 51 is carried out under such a condition that this first film 51 is heated. As previously explained, if the first film 51 is once heated, then this first film 51 is softened. As a result, the adhering operation of the first film 51 is carried out under the softened condition. For example, while the first film 51 is heated at approximately 80° C., this heated first film 51 is adhered.

As a result, when the first film 51 is adhered, as shown in FIG. 3A, such a condition that the bump 40a formed on the side of the sensorchip 10 is caved in the softened first film 51 is realized.

As indicated in FIG. 3A, after the above-explained adhering step, one plane of the sensor chip 10 is positioned opposite to one plane of the circuit chip 20 to perform positioning of the bumps 40a and 40b of the chips 10 and 20, respectively, and then, a connecting step is performed.

In the connecting step, as represented in FIG. 3B, the bump 40b formed on the side of the circuit chip 20 is depressed with respect to the first film 51 on the sensor chip 10. As a result, the bump 40b formed on the side of the circuit chip 20 breaks through the first film 51, so that the bump 40a formed on the side of the sensor chip 10 is made in contact with the bump 40b formed on the side of the circuit chip 20.

In this step, while the first film 51 is brought into such a condition that the first film 51 is heated so as to be softened, the bump 40b of the circuit chip 20 breaks through the first film 51 under this softened condition, and an electric connection between the bump 40a of the sensor chip 10 and the bump 40b of the circuit chip 20 is carried out. Concretely speaking, a heating temperature is increased higher than that of the above-explained adhering step, for example, under such a condition that the heating operation is carried out at 150° C. for several seconds, the connection step is performed.

As a result, in this connection step, the first film 51 softened by being heated receives weight from the bump 40b of the circuit chip 20 to be deformed, and then is broken through by this bump 40b. Then, under such a condition that both the bump 40a of the sensor chip 10 is contacted to the bump 40b of the circuit chip 20, an ultrasonic joining operation is carried out. As a result, both the bumps 40a and 40b are metal-joined to each other so as to be integrally processed, so that such a bump 40 for joining both the chips 10 and 20 to each other may be formed. As a consequence, an electrical connection may be accomplished.

Next, the resulting sensor apparatus is returned to the room temperature, and thereafter, a sealing step is carried out. In this sealing step, the first film 51 is furthermore heated so as to be softened, so that a peripheral portion of the formed bump 40 is sealed by the first film 51. For example, the sealed bump 40 is heated for 1 hour at a temperature substantially equal to that of the above-explained connection step, for example, 150° C.

As a result, the first film 51 is hardened under such a condition as represented in FIG. 3B. Then, since the first film 51 is hardened, the hardened first film 51 is adhered onto both one plane of the sensor chip 10 and one plane of the circuit chip 20, so that the bump 40 is sealed. Accordingly, the connection between the sensor chip 10 and the circuit chip 20 via the bump 40 is accomplished.

After the bumps 41a and 41b of both the sensor and circuit chips 10 and 20 are joined to each other, a second film 52 is joined to the other plane of the sensor chip 10. This joining process may be carried out in a similar manner to the above-explained adhering operation of the first film 51.

Thereafter, both the sensor chip 10 and the circuit chip 20 which have been processed in an integral body via a bump 41 positioned at the outer peripheral portion of the sensor chip 10 in the circuit chip 20 are joined to the package 30. It should also be noted that this bump 41 may be alternatively formed on the circuit chip 20 at the same time when the bump 40b shown in FIG. 3A is formed in the circuit chip 20. Otherwise, this bump 41 may be formed after both the chips 10 and 20 have been joined to each other. Then, the joining process between the circuit chip 20 and the package 30 may be carried out by employing the above-explained ultrasonic joining process.

Thereafter, under such a condition that, for example, nitrogen gas is filled into the package 30, the above-explained lid portion 32 is mounted with respect to the package 30. As a result, the angular velocity sensor apparatus 100 shown in FIG. 1 may be accomplished.

In the manufacturing method shown in FIG. 3, the first film 51 is provided on one plane side of the sensor chip 10, and thereafter, the bump joining process operation is carried out. In this example, since the first film 51 is adhered to both the chips 10 and 20, conversely, the first film 51 may be provided on one side of the circuit board 20, and thereafter, the bump joining process operation may be alternatively carried out.

Furthermore, in the above-explained manufacturing method, the bumps 40a and 40b are provided on planes of both the chips 10 and 20, respectively, and then, the bump joining process operation is carried out. Alternatively, a bump may be provided only on the side of the sensor chip 10, otherwise, a bump may be provided only on the side of the circuit chip 20, and thereafter, a bump joining process operation may be carried out. In this alternative case, the pad 12 on the side of the chip where this bump is provided may be joined to the pad 21 on the side of the chip where the bump is not provided by way of an ultrasonic joining method similar to the above-explained method.

Also, the joining process operation of the second film 52 need not be carried out after both the chips 10 and 20 are joined to each other. For example, if there is no problem in the joining process operation, then the second film 52 may be adhered at the same time when the first film 51 is adhered to the sensor chip 10 before the sensor chip 10 is joined to the circuit chip 20.

On the other hand, in the angular velocity sensor apparatus 100 of this first embodiment, the sensor chip 10 and the circuit chip 20 have been stacked on each other, and both these chips 10 and 20 have be electrically connected via the bumps. This sensor chip 10 corresponds to such a semiconductor chip having the vibrator 11 on one plane thereof, while this vibrator 11 functions as the sensing portion for detecting the angular velocities.

Then, in such a sensor apparatus 100, the sensor chip 10 has been stacked via the bump 40 on the circuit chip 20 while this vibrator 11 is located opposite to one plane of the circuit chip 20; the first film 51 which is made of the resin and covers the vibrator 11 has been joined to one plane of the sensor chip 10; and the second film 52 made of the resin has been joined to the other plane of the sensor chip 10.

The sensor chip 10 is made of the semiconductor, for example, silicon (Si). Also, in this example, both the films 51 and 52 are made of the epoxy series resin, and the package 30 is made of ceramics.

In this case, the linear expansion coefficient of Si is given by α=2.3 ppm/° C., and the Young's modulus thereof is given by E =170 GPa; the linear expansion coefficients of the films 51 and 52 are given by α=30 ppm/° C., and the Young's modulus thereof is given by E=8 GPa; and the linear expansion coefficient of the package 30 is given by α=7 ppm/° C., and the Young's modulus thereof is given by E=310 GPa. As a result, the distortions may occur at the highest degree between the films 51 and 52, and the sensor chip 10 due to a difference in the thermal expansion coefficients.

However, in this first embodiment, not only the first film 51 made of the resin is joined to the sensor chip 10, but also the second film 52 made of the resin is joined to the other plane of the sensor chip 10 provided on the opposite side as to the above-explained one plane thereof. As a result, the stresses (distortions) caused by the linear expansion coefficient difference between the sensor chip 10 and the films 51 and 52 can be made equal to each other as being permitted as possible.

More specifically, in this example, since the first and second films 51 and 52 are made of the same material on both one plane and the other plane of the sensor chip 10, the linear expansion coefficients of both the films 51 and 52 may be easily made equal to each other, so that the above-described stresses produced on both the planes of the sensor chip 10 may be readily made equal to each other.

As previously explained, in accordance with this first embodiment, the stresses may be produced which are caused by the difference in the linear expansion coefficients between the sensor chip 10 and the resin films 51 and 52 on both the planes of the sensor chip 10. As a result, when the temperature cycle is produced, the deformation of the sensor chip 10 due to this difference in these linear expansion coefficients can be suppressed.

Also, in this first embodiment, since the first film 51 is joined to one plane of the sensor chip 10 under such a condition that this first film 51 is separated from the vibrator 11, it is possible to avoid that the first film 51 interferes with the vibrator 11, and thus, the characteristics (for example, vibration characteristic) of the vibrator 11 are impeded.

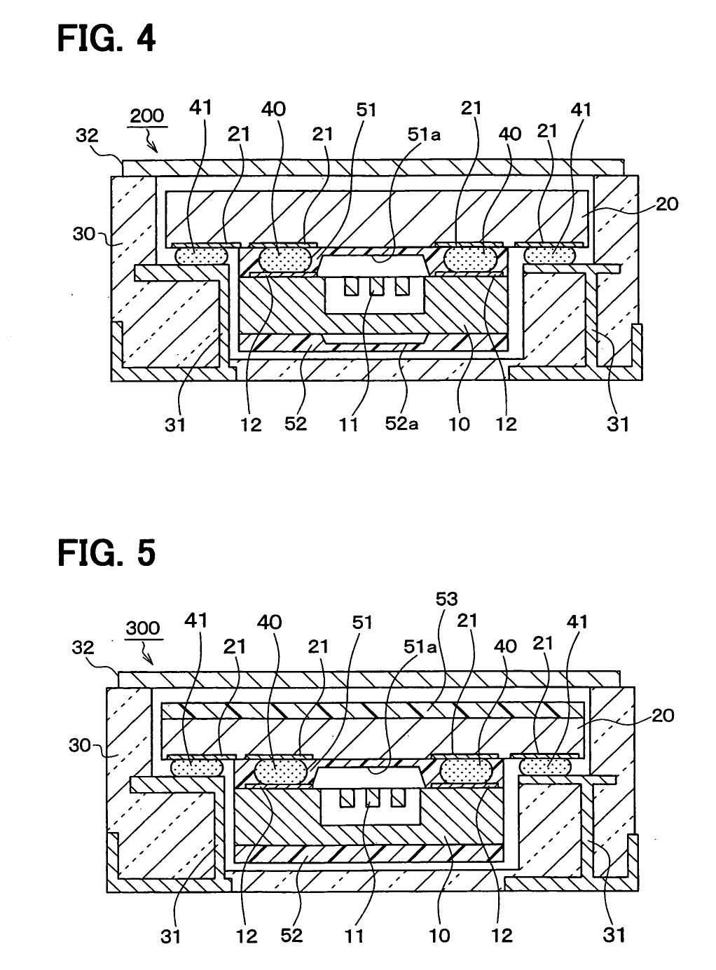

FIG. 4 is a sectional view for schematically showing an entire structure of an angular velocity sensor apparatus 200 functioning as a sensor apparatus according to a second example embodiment. In this second embodiment, the second film 52 joined to the other plane of the sensor chip 10 is modified with respect to the above-explained first embodiment.

In the above-explained first embodiment, the second film 52 has been joined to the other plane of the sensor chip 10 by being contacted to the entire portion of the other plane. In this second embodiment, as shown in FIG. 4, the second film 52 has been joined to the other plane of the sensor chip 10 under such a condition that the second film 52 is separated from a portion of the other plane of the sensor chip 10, which corresponds to the vibrator 11.

In this example, in the second film 52, a concave 52a has been formed in a portion of the other plane of the sensor chip 10, which corresponds to the vibrator 11. The second film 52 is separated from the other plane of the sensor chip 10 in this concave 52a.

Concretely speaking, in this example, it is so designed that the second film 52 owns the same concave shape as that of the first film 51. In other words, a plane shape of the second film 52 of this example is made identical to the plane shape of the first film 51 shown in FIG. 2.

As a consequence, both one plane and the other plane of the sensor chip 10 at the portion of the vibrator 11 are separated from the first film 51 and the second film 52, which are made of the resin, so that a more advantageous structure can be realized in order to suppress distortions of the vibrator 11 due to the temperature cycle.

Also, if the areas of such portions of the first film 51 and the second film 52, which are joined to the sensor chip 10, are made equal to each other, namely, the joining areas are made equal to each other, then the stresses caused by a difference in linear expansion coefficients between the sensor chip 10 and the first and second films 51 and 52 may be easily made equal to each other as being permitted as possible on both one plane and the other plane of the sensor chip 10.

Moreover, if plane patterns of portions joined to the sensor chip 10, namely, patterns of the joining regions are made equal to each other after the joining areas are made equal to each other, then the stresses caused by the above-explained linear expansion coefficients difference may be more easily made equal to each other.

As explained in this second embodiment, the second film 52 is separated from the sensor chip 10 at the same portion as the first film 51. As a result, the joining areas of these first and second films 51 and 52, and also the patterns of the joining regions can be resembled to each other as being permitted as possible.

More specifically, as explained in this example, both the first film 51 and the second film 52 may have the same concave shapes, so that the joining areas and the patterns of the joining regions in the first film 51 and the second film 52 can be made equal to each other.

Also, in order to make the joining areas and the patterns of the joining regions as to the first and second films 51 and 52 equal to each other, the film shapes of both the first and second films 51 and 52 may not be identical to each other; may be different from each other; or the sizes of these first and second films 51 and 52 may be different from each other. For instance, the adhesive characteristics of partial regions in the first film 51 and the second film 52 are invalidated, so that the joining areas and the patterns of the joining regions may be easily adjusted.

FIG. 5 is a sectional view for schematically showing an entire structure of an angular velocity sensor apparatus 300 functioning as a sensor apparatus according to a third example embodiment.

This third embodiment may be applied to the first and second embodiments, and is featured as follows: That is, with respect to each of the above-explained respective embodiments, a third film 53 made of a resin is joined to one plane of the circuit chip 20, namely, the other plane of the circuit chip 20, which is located on the reverse side with respect to a plane opposite to the sensor chip 10. This third film 53 is made of such a similar resin which is selected from the above-described resins of the first film 51 and the second film 52.

In the above-explained embodiments, since the first film 51 is joined to one plane of the circuit chip 20, there are some possibilities that the circuit chip 20 may also be curved due to the linear expansion coefficient difference between the circuit chip 20 and the first film 51 due to the temperature cycle. In the case that the circuit chip 20 is curved, there is a risk that the sensor chip 10 joined via the bump 40 to this circuit chip 20 may also be curved.

To the contrary, as explained in this third embodiment, in the circuit chip 20, the third film 53 made of the resin is joined on not only one plane of this circuit chip 20, but also the other plane thereof located opposite to one plane. As a result, the circuit chip 20 owns stresses on both the planes thereof due to a difference in linear expansion coefficients between the circuit chip 20 and the first film 51.

As a result, in accordance with this third embodiment, the deformations of the circuit chip 20 caused by the difference in the linear expansion coefficients can be suppressed. Thus, the deformations of the circuit chip 20 may be suppressed, which may conduct to prevent the deformation of the sensor chip 10.

Also, as explained in this third embodiment, in such a case that the first film 51 and the third film 53 which are made of the resin are joined to both the planes of the circuit chip 20, these first and third films 51 and 53 may be made of the same materials, and the joining areas and the patterns of the joining regions may be made equal to each other in the first film 51 and the third film 53 joined to both the planes of this circuit chip 20 in a similar manner to that of the case of the sensor chip 10 shown in FIG. 4.

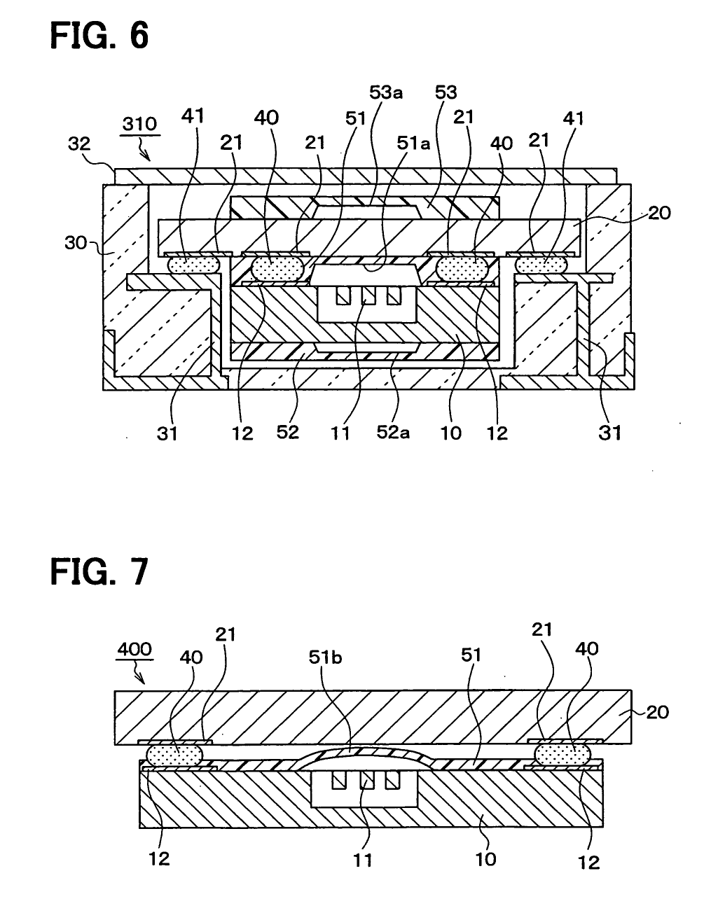

Also, FIG. 6 is a diagram for showing a sectional view which schematically indicates an entire structure of an angular velocity sensor apparatus 310 as another example related to this third embodiment.

In this example, it is so assumed that three sheets of films, namely the first film 51, the second film 52, and the third film 53 have the same shapes and the same sizes with each other, these three films 51 to 53 are provided at the same position in such a manner that the entire films 51 to 53 are substantially overlapped with each other, as viewed from the stacking direction (upper/lower direction in FIG. 6) of the sensor chip 10 and the circuit chip 20.

In this example, it is so assumed that the three films 51 to 53 have the same outer peripheral shapes as that of the sensor chip 10, the third film 53 is arranged on a portion of the other plane of the circuit chip 20, which corresponds to the sensor chip 10.

As a result, in the case that this angular velocity sensor apparatus 310 is viewed from the upper direction of FIG. 6, namely from the other plane of the circuit chip 20, three sheets of the first to third films 51 to 53 are overlapped with each other, while the positions of these first to third films 51 to 53 are not essentially shifted.

Also, in the example shown in FIG. 6, any of three sheets of the first to third films 51 to 53 own a concave 51a to a concave 53a, and are made of the same material. In other words, in this example, if three sheets of films are prepared which are essentially identical to each other, then one sheet of these three films may be used for any of the first film 51, the second film 52, and the third film 53. This feature has a merit in view of productivity.

FIG. 7 is a sectional view for schematically showing a major structure of an angular velocity sensor apparatus 400 functioning as a sensor apparatus according to a fourth example embodiment. This fourth embodiment is featured by that in the above-explained first embodiment, a first film 51 interposed between the sensor chip 10 and the circuit chip 20 is modified.

In the above-described first embodiment, the first film 51 owns such a thickness by which the space between the sensor chip 10 and the circuit chip 20 may be embedded. As a result, the first film 51 is joined to not only one plane of the sensor chip 10, but also one plane of the circuit chip 20.

In contrast to the first embodiment, as represented in FIG. 7, in this fourth embodiment, a thickness of the first film 51 is made smaller than an interval between the sensor chip 10 and the circuit chip 20 secured by the bump 40; the first film 51 is joined only to one plane of the sensor chip 10; and the first film 51 is separated from one plane of the circuit chip 20.

Also, in this fourth embodiment, the first film 51 has been joined to one plane of the sensor chip 10 under such a condition that this first film 51 is separated from the vibrator 11. Concretely speaking, the first film 51 has constituted such a convex 51b that a portion of this first film 51 corresponding to the vibrator 11 has a convex shape in such a direction along which this portion is separated from the vibrator 11.

As a result, the vibrator 11 can be properly separated from the first film 51 by this convex 51b. Furthermore, similar to the first film 51 of the above-described embodiment, since the vibrator 11 is covered by this convex 51b of the first film 51, it is possible to avoid that alien substances are penetrated to the vibrator 11.

It should be understood that such a convex 51b may be formed in such a way that, for example, the first film 51 is curved so as to be joined to the sensor chip 10, or is plastic-deformed by a thermal pressing method. Thus, the angular velocity sensor apparatus 400 of this fourth embodiment can be manufactured by employing the first film 51 where the above-explained convex 51b has been provided in a similar manner to that of the first embodiment. Also, this fourth embodiment may be applied to the above-explained second embodiment and third embodiment.

It should also be noted that in order to separate the first film 51 from the vibrator 11 corresponding to the sensing portion, any other members than the above-explained concave 51a and convex 51b may be alternatively employed. Also, in such a case that a sensing portion is arranged in such a manner that this sensing portion is concaved from one plane of a semiconductor chip, even when a first film is made in a plane shape, this first film may be separated from the sensing portion.

Furthermore, even when a sensing portion is made in contact with a first film, in the case that there is no essentially effect as to a sensing characteristic of this sensing portion, the first film may be contacted to the sensing portion, and furthermore, may be joined to the sensing portion.

Also, in the above-explained embodiments, the sensor chip 10 is connected to the circuit chip 20 by the bump 40 by employing the ultrasonic joining method. Alternatively, various sorts of bump connecting methods may be employed.

Also, in the above-explained embodiments, the circuit chip 20 has been connected to the package 30 by way of the bump 41 with respect to one plane thereof, namely, the bump connecting plane with the sensor chip 10. For instance, in FIG. 1 while the stacked member constituted by the circuit chip 20 and the sensor chip 10 is brought into an inverted condition along the upper and lower direction, the circuit chip 20 may be alternatively joined to the package 30 by the bump 41 on the other plane of this circuit chip.

Furthermore, the circuit chip 20 may be alternatively connected to the package 30 by employing any other connecting methods than the bump 41, for example, by way of a bonding wire.

It should also be understood that the present invention is not limited only to the above-explained angular velocity sensor apparatus, but may be alternatively applied to other sensor apparatus, if these sensor apparatus are manufactured in such a manner that a semiconductor chip and a circuit chip are stacked on each other, and these semiconductor and circuit chips are electrically connected to each other via a bump, while a sensing portion for sensing a mechanical amount is provided on one plane of the semiconductor chip.

For example, the present invention may be alternatively applied to such an acceleration sensor equipped with a semiconductor chip having a sensing portion on one plane thereof and this sensing portion is realized by a movable electrode, or a movable weight; a pressure sensor equipped with a semiconductor chip having a sensing portion such as a diagram; and the like.

The present disclosure has the following aspects.

According to a first aspect of the present disclosure, a sensor includes: a semiconductor chip having a sensing portion for detecting a physical quantity; a circuit chip; and first and second films. The sensing portion is disposed on a first side of the semiconductor chip. The first side of the semiconductor chip is electrically connected to the circuit chip through a bump. The first side of the semiconductor chip faces the circuit chip so that the sensing portion also faces the circuit chip. The first film is disposed on the first side of the semiconductor chip. The first film covers the sensing portion, and is made of resin, and the second film is made of resin, and disposed on a second side of the semiconductor chip.

In the above device, the semiconductor chip is sandwiched between the first and second films. Therefore, both interfaces between the semiconductor chip and the first and second films have stress. The stress is caused by a difference of linear coefficient of expansion between the semiconductor chip and the first or second film. Accordingly, deformation of the semiconductor chip caused by the difference of linear coefficient of expansion is reduced.

Alternatively, the first film may be made of a same material as the second film. In this case, the linear coefficient of expansion of the first film is equal to that of the second film.

Alternatively, the first film may separate from the sensing portion, and the first film is bonded to the first side of the semiconductor chip. In this case, characteristics of the sensing portion are not deteriorated by the first film. Further, the first film may include a concavity, and the concavity faces the sensing portion so that the first film separates from the sensing portion.

Alternatively, the second film may separate from a part of the second side of the semiconductor chip. The part of the second side corresponds to the sensing portion and opposite to the sensing portion, and the second film is bonded to the second side of the semiconductor chip. In this case, the sensing portion and the part of the second side of the semiconductor chip separate from the first and second films. Accordingly, distortion of the sensing portion caused by thermal cycle is reduced. Further, the second film may include a concavity, and the concavity faces the part of the second side of the semiconductor chip so that the second film separates from the part of the second side of the semiconductor chip.

Alternatively, the first film may be bonded to the semiconductor chip with a first bonding area, and the second film is bonded to the semiconductor chip with a second bonding area, which is substantially equal to the first bonding area. Further, the first bonding area may have a first planar pattern, and the second bonding area has a second planar pattern, which is substantially equal to the first planar pattern. In the above cases, the stress caused by the difference of linear coefficient of expansion between the semiconductor chip and the first film is equal to that between the semiconductor chip and the second film.

Alternatively, the first film may be bonded to the first side of the semiconductor chip, and the first film is bonded to the circuit chip so that the first film connects between the first side of the semiconductor chip and the circuit chip. In this case, the semiconductor chip and the circuit chip are mechanically connected and supported each other by the first film. Thus, the bonding strength between them is improved.

Alternatively, the sensor may further include a third film. The circuit chip includes first and second sides. The first side of the circuit chip faces the first side of the semiconductor chip. The third film is disposed on the second side of the circuit chip. The third film is made of resin, and bonded to the second side of the circuit chip. In this case, both sides of the circuit chip are also bonded to the first and third films. Thus, deformation of the circuit chip caused by thermal cycle is reduced. Further, the third film may be made of a same material as the first film. Further, the first film may be bonded to the semiconductor chip with a first bonding area, and the third film is bonded to the circuit chip with a third bonding area, which is substantially equal to the first bonding area. Furthermore, the first bonding area may have a first planar pattern, and the third bonding area has a third planar pattern, which is substantially equal to the first planar pattern. Further, the first film may have a first planar pattern, the second film may have a second planar pattern, which is substantially equal to the first planar pattern, and the third film may have a third planar pattern, which is substantially equal to the first planar pattern. The second film, the semiconductor chip, the first film, the circuit chip and the third film are stacked in a stacking direction in this order, and the second film, the first film and the third film are overlapped along with the stacking direction.

According to a second aspect of the present disclosure, a sensor includes: a semiconductor chip having a sensing portion for detecting a physical quantity; a circuit chip; first and second films; and a solder bump for electrically connecting between the semiconductor chip and the circuit chip. The second film, the semiconductor chip, the first film, and the circuit chip are stacked in a stacking direction in this order. The semiconductor chip includes first and second sides. The circuit chip includes first and second sides. The first side of the semiconductor chip is electrically connected to the first side of the circuit chip through the bump so that the bump is embedded in the first film. The sensing portion is disposed on the first side of the semiconductor chip. The sensing portion separates from the first film so that a space is provided between the sensing portion and the first film. The first film is made of resin, and the second film is made of resin.

In the above device, the semiconductor chip is sandwiched between the first and second films. Therefore, both interfaces between the semiconductor chip and the first and second films have stress. The stress is caused by a difference of linear coefficient of expansion between the semiconductor chip and the first or second film. Accordingly, deformation of the semiconductor chip caused by the difference of linear coefficient of expansion is reduced.

Alternatively, the first film may be made of a same material as the second film. The first film includes a concavity so that the space between the sensing portion and the first film is provided. The first side of the semiconductor chip and the first side of the circuit chip are bonded with the first film. The second film is bonded to the second side of the semiconductor chip. The second film separates from a part of the second side of the semiconductor chip. The part of the second side corresponds to the sensing portion and opposite to the sensing portion. The second film includes a concavity, and the concavity faces the part of the second side of the semiconductor chip so that the second film separates from the part of the second side of the semiconductor chip.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A sensor comprising:
a semiconductor chip having a sensing portion for detecting a physical quantity;
a circuit chip; and
first and second films, wherein
the sensing portion is disposed on a first side of the semiconductor chip,
the first side of the semiconductor chip is electrically connected to the circuit chip through a bump,
the first side of the semiconductor chip faces the circuit chip so that the sensing portion also faces the circuit chip,
the first film is disposed on the first side of the semiconductor chip,
the first film covers the sensing portion, and is made of resin, and
the second film is made of resin, and disposed on a second side of the semiconductor chip.

2. The sensor according to claim 1, wherein
the first film is made of a same material as the second film.

3. The sensor according to claim 1, wherein
the first film separates from the sensing portion, and
the first film is bonded to the first side of the semiconductor chip.

4. The sensor according to claim 3, wherein
the first film includes a concavity, and
the concavity faces the sensing portion so that the first film separates from the sensing portion.

5. The sensor according to claim 3, wherein
the second film separates from a part of the second side of the semiconductor chip,
the part of the second side corresponds to the sensing portion and opposite to the sensing portion, and
the second film is bonded to the second side of the semiconductor chip.

6. The sensor according to claim 5, wherein
the second film includes a concavity, and
the concavity faces the part of the second side of the semiconductor chip so that the second film separates from the part of the second side of the semiconductor chip.

7. The sensor according to claim 1, wherein
the first film is bonded to the semiconductor chip with a first bonding area, and
the second film is bonded to the semiconductor chip with a second bonding area, which is substantially equal to the first bonding area.

8. The sensor according to claim 7, wherein
the first bonding area has a first planar pattern, and
the second bonding area has a second planar pattern, which is substantially equal to the first planar pattern.

9. The sensor according to claim 1, wherein
the first film is bonded to the first side of the semiconductor chip, and
the first film is bonded to the circuit chip so that the first film connects between the first side of the semiconductor chip and the circuit chip.

10. The sensor according to claim 1, further comprising:
a third film, wherein
the circuit chip includes first and second sides,
the first side of the circuit chip faces the first side of the semiconductor chip,
the third film is disposed on the second side of the circuit chip, and
the third film is made of resin, and bonded to the second side of the circuit chip.

11. The sensor according to claim 10, wherein
the third film is made of a same material as the first film.

12. The sensor according to claim 10, wherein
the first film is bonded to the semiconductor chip with a first bonding area, and
the third film is bonded to the circuit chip with a third bonding area, which is substantially equal to the first bonding area.

13. The sensor according to claim 12, wherein
the first bonding area has a first planar pattern, and
the third bonding area has a third planar pattern, which is substantially equal to the first planar pattern.

14. The sensor according to claim 10, wherein
the first film has a first planar pattern,
the second film has a second planar pattern, which is substantially equal to the first planar pattern,
the third film has a third planar pattern, which is substantially equal to the first planar pattern,
the second film, the semiconductor chip, the first film, the circuit chip and the third film are stacked in a stacking direction in this order, and
the second film, the first film and the third film are overlapped along with the stacking direction.

15. A sensor comprising:
a semiconductor chip having a sensing portion for detecting a physical quantity;
a circuit chip;
first and second films; and
a solder bump for electrically connecting between the semiconductor chip and the circuit chip, wherein
the second film, the semiconductor chip, the first film, and the circuit chip are stacked in a stacking direction in this order,
the semiconductor chip includes first and second sides,
the circuit chip includes first and second sides,
the first side of the semiconductor chip is electrically connected to the first side of the circuit chip through the bump so that the bump is embedded in the first film,
the sensing portion is disposed on the first side of the semiconductor chip,
the sensing portion separates from the first film so that a space is provided between the sensing portion and the first film,
the first film is made of resin, and
the second film is made of resin.

16. The sensor according to claim 15, wherein
the first film is made of a same material as the second film,
the first film includes a concavity so that the space between the sensing portion and the first film is provided,
the first side of the semiconductor chip and the first side of the circuit chip are bonded with the first film,
the second film is bonded to the second side of the semiconductor chip,
the second film separates from a part of the second side of the semiconductor chip,
the part of the second side corresponds to the sensing portion and opposite to the sensing portion,
the second film includes a concavity, and
the concavity faces the part of the second side of the semiconductor chip so that the second film separates from the part of the second side of the semiconductor chip.
